(19) United States
(12) Patent Application Publication
(10) Pub. No.: US 2026/0368400 A1
(43) Pub. Date: Nov. 19, 2026

(54) SYSTEMS, METHODS, AND STORAGE MEDIA TO MODEL BLAST TRANSFORMATION OF AN IN-SITU MATERIAL COMPOSITION INTO A MUCKPILE VOLUME FOR UPDATING A POST-BLAST DIG PLAN FOR A MINE SITE

(71) Applicant: AUGMENT: EXPERT SYSTEMS PTY LTD, Subiaco (AU)

(72) Inventor: Brice Clinton GOWER, Rivervale (AU)

(21) Appl. No.: 19/146,864

(22) PCT Filed: Jan. 11, 2024
(86) PCT No.: PCT/AU2024/050015

§ 371 Date: Jul. 9, 2025

(30) Foreign Application Priority Data
Jan. 11, 2023 (AU) 2023900058

(51) Int. Cl. G06F 30/27

(52) U.S. Cl. CPC G06F 30/27

(57) ABSTRACT

Systems, methods, and storage media to model blast transformation of an in-situ material composition into a muckpile volume for generating a post-blast dig plan for a mine site are disclosed. Exemplary implementations may: receive initial parameters of the in-situ material composition; collate a blast instance file representing the initial parameters; execute a machine learning simulation to generate a muckpile block model of in situ blocks; mark particular blocks in the muckpile block model as absent air blocks; discretely relocate each block to a final location within the muckpile block model; append a transformation file to an initial blast instance file; and provide a transformed model for a user to generate an accurate mark out to create the post-blast dig plan based on changes a blast had on a material composition of the in-situ volume as defined in the muckpile block model.

### FIELD OF THE DISCLOSURE

The present disclosure relates to systems, methods, and storage media to model blast transformation of an in-situ material composition into a muckpile volume for creating a post-blast dig plan for a mine site.

### BACKGROUND

Open-cut mining operations employ explosives to blast rock in sections to fragment the rock into a size that can be moved efficiently (the “in-situ volume”). Following the blast, heavy machinery removes ore from the resulting “muckpile,” according to a post-blast dig plan. The dig plan coordinates the destination of where the material should be moved to, such that the mine can manage stockpiles, blending operations, and waste management.

Blast movement refers to movement of the materials found in the muckpile relative to the in-situ volume. Updating the post-blast dig plan to account for blast movement can reduce “ore loss” (sending valuable material to the waste pile), “ore dilution” (lowing the grade of ore due to waste mixing in), and/or “ore mixing” (combining different material types in a manner that causes inefficient processing).

Techniques for creating and/or updating the post-blast dig plan include Blast Movement Instruments (BVIs). BVIs are devices positioned in the in-situ volume, and then located in the muckpile. Linear extrapolation software models incorporate data from BVIs and/or surveys of the resultant muckpile to interpolate displacement of the valuable materials.

Unfortunately, additional drilling to place BVIs is costly, and walking over the muckpile to find BVIs can be dangerous. BVIs are often lost during the blast, reducing the vectors available to accurately determine blast movement. In addition, the process is usually heuristic, being left open to interpretation by the shift geologist or blast engineer.

### SUMMARY

One aspect of the present disclosure relates to a system configured to model blast transformation of an in-situ material composition into a muckpile volume for creating or generating a post-blast dig plan for a mine site. The process produces a model of the muckpile, which is used to create the dig plan; instead of being based on the in-situ plan and then updating that.

The system may include one or more hardware processors configured by machine-readable instructions. The processor(s) may be configured to receive initial parameters of the in-situ material composition. The processor(s) may be configured to collate a blast instance file representing the initial parameters as a high-resolution block model encoding at least one of grade control, drill and blast parameters, site surveys, blast vector instrument (BVI) data, and custom strings. The processor(s) may be configured to execute a simulation and/or machine learning simulation to generate a muckpile block model from the information in the in-situ model. Each in situ block may have a unique 3D predicted vector use to model how the material has moved into the muckpile volume. The processor(s) may be configured to mark particular blocks in the muckpile block model as absent air blocks such that these locations are now unavailable, in order to model the expansion of the volume whilst maintaining conservation of mass, the air blocks now mean that within the model, the total available blocks within the muckpile block model may be equal to in situ blocks available to relocate. The processor(s) may be configured to discretely relocate each block to a final location within the muckpile block model, fitting to the simulated 3D vectors. The processor(s) may be configured to append a transformation file to an initial blast instance file. The processor(s) may be configured to provide a transformed model for a user to generate an accurate mark out to create update the post-blast dig plan based on changes a blast had on a material composition of the in-situ volume as defined in the muckpile block model.

In some implementations of the system, the in-situ material composition may include at least one of a geological grade control block model, measurements of drilling and blasting parameters, planned and/or drill and blast data, blast vector instrument (BVI) data, and surface scans surveying a pre-blast surface and a post-blast surface.

In some implementations of the system, the processor(s) may be configured to train a bespoke machine learning policy for the mine site.

In some implementations of the system, the bespoke machine learning policy may be based on a dataset of blasts.

In some implementations of the system, the dataset of blasts may be from the mine site.

In some implementations of the system, the dataset of blasts may be supplemented with another dataset of blasts from a different mine site.

In some implementations of the system, the bespoke machine learning policy may be a general policy based on generalized mine site data.

Another aspect of the present disclosure relates to a method to model blast transformation of an in-situ material composition into a muckpile volume for creating and/or updating a post-blast dig plan for a mine site. The method may include receiving initial parameters of the in-situ material composition. The method may include collating a blast instance file representing the initial parameters as a high-resolution block model encoding at least one of grade control, drill and blast parameters, site surveys, blast vector instrument (BVI) data, and custom strings. The method may include executing a machine learning simulation to generate a muckpile block model of in situ blocks. Each in situ block may have a unique 3D predicted vector in the muckpile volume. The method may include marking particular blocks in the muckpile block model as absent air blocks such that these locations are now unavailable. Total available blocks within the muckpile block model may be equal to in situ blocks available to relocate. The method may include discretely relocating each block to a final location within the muckpile block model, fitting to the simulated 3D vectors. The method may include appending a transformation file to an initial blast instance file. The method may include providing a transformed model for a user to generate an accurate mark out to create update the post-blast dig plan based on changes a blast had on a material composition of the in-situ volume as defined in the muckpile block model.

In some implementations of the method, the in-situ material composition may include at least one of a geological grade control block model, measurements of drilling and blasting parameters, planned drill and blast data, blast vector instrument (BVI) data, and surface scans surveying a pre-blast (i.e., in situ) surface and a post-blast (i.e., muckpile) surface.

In some implementations of the method, it may include further including training a bespoke machine learning policy for the mine site.

In some implementations of the method, the bespoke machine learning policy may be based on a dataset of blasts.

In some implementations of the method, the dataset of blasts may be from the mine site.

In some implementations of the method, the dataset of blasts may be supplemented with another dataset of blasts from a different mine site.

In some implementations of the method, the bespoke machine learning policy may be a general policy based on generalized mine site data.

Yet another aspect of the present disclosure relates to a non-transient computer-readable storage medium having instructions embodied thereon, the instructions being executable by one or more processors to perform a method to model blast transformation of an in-situ material composition into a muckpile volume for creating and/or updating a post-blast dig plan for a mine site. The method may include receiving initial parameters of the in-situ material composition. The method may include collating a blast instance file representing the initial parameters as a high-resolution block model encoding at least one of grade control, drill and blast parameters, site surveys, blast vector instrument (BVI) data, and custom strings. The method may include executing a machine learning simulation to generate a muckpile block model of in situ blocks. Each in situ block may have a unique 3D predicted vector in the muckpile volume. The method may include marking particular blocks in the muckpile block model as absent air blocks such that these locations are now unavailable. Total available blocks within the muckpile block model may be equal to in situ blocks available to relocate. The method may include discretely relocating each block to a final location within the muckpile block model, fitting to the simulated 3D vectors (for example, but not a limiting disclosure, performing a correlation or measure of each of the 3D predicted vectors with the volume that they individually represent). The method may include appending a transformation file to an initial blast instance file. The method may include providing a transformed model for a user to generate an accurate mark out to update the post-blast dig plan based on changes a blast had on a material composition of the in-situ volume as defined in the muckpile block model.

In some implementations of the computer-readable storage medium, the in-situ material composition may include at least one of a geological grade control block model, measurements of drilling and blasting parameters, planned drill and blast data, blast vector instrument (BVI) data, and surface scans surveying a pre-blast surface and a post-blast surface.

In some implementations of the computer-readable storage medium, the method may include further including training a bespoke machine learning policy for the mine site.

In some implementations of the computer-readable storage medium, the bespoke machine learning policy may be based on a dataset of blasts.

In some implementations of the computer-readable storage medium, the dataset of blasts may be from the mine site.

In some implementations of the computer-readable storage medium, the dataset of blasts may be supplemented with another dataset of blasts from a different mine site.

As previously stated, open-cut mining operations employ explosives to blast rock in sections to fragment the rock into a size that can be moved efficiently. Mine planning decides what sections to blast, and each volume is referred to as “in situ” or pre-blast volume. The terms “muckpile” or “post-blast volume” used throughout this specification refer to resultant material once the blast has fragmented and moved the in situ volume.

Blast movement refers to movement of the materials found in the muckpile relative to the in-situ volume. A plan made prior to the blast is referred to as a pre-blast dig plan, which will apply economic and geochemical considerations to the in situ volume without understanding how the blast will change the material composition that is actually mined as the muckpile volume. Updating the dig plan post blast to account for blast movement minimizes error, and tools such as Blast Vector Instruments (BVIs) improve the accuracy but still leave margin for improvement.

The term “dig plans” refers to plans that coordinate the specific loading equipment based on the logistical requirements of the mine, operating as a decision matrix for sending various material types to a finite number of destinations. Without accurate spatial knowledge of the post-blast muckpile, dig plans will be a large source of error for metal recovery, affecting stockpile management, blending operations, and waste rock disposal. Three categories of these errors include “ore loss” (sending valuable material to the waste pile), “ore dilution” (lowering the grade of ore due to waste mixing in), and/or “ore mixing” (combining different material types in a manner that causes inefficient processing).

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### BRIEF DESCRIPTION OF THE DRAWINGS

FIG. 1 illustrates an example actual geologic profile of a mining operation pre-blast, in accordance with one or more implementations.

FIG. 2 illustrates an example geologic profile of the mining operation post-blast, in accordance with one or more implementations.

FIGS. 3A and 3B illustrate an example policy development process and deployment, in accordance with one or more implementations.

FIGS. 4A and 4B illustrate an example mining operation according to a policy development process and corresponding ore movement policy, in accordance with one or more implementations.

FIG. 5 illustrates a system configured to model blast transformation of an in-situ material composition into a muckpile volume for creating and/or updating a post-blast dig plan for a mine site, in accordance with one or more implementations.

FIGS. 6A, 6B, 6C, 6D, 6E, and/or 6F illustrates a method to model blast transformation of an in-situ material composition into a muckpile volume for creating and/or updating a post-blast dig plan for a mine site, in accordance with one or more implementations.

### DETAILED DESCRIPTION

The present disclosure relates to model blast transformation of an in-situ material composition into a muckpile volume for creating and/or updating a post-blast dig plan for a mine site. Mining operations need to recover the highest percentage of valuable material from the ore in order to be profitable. Failing to accurately understand the effect of blast movement when implementing a post-blast dig plan can leave the mining operation with a significant quantity of ore that is not able to be recovered in a profitable manner.

Implementations described herein address the aforementioned shortcomings and other shortcomings by providing a three-dimensional (3D) artificial intelligence (Al) driven blast movement determination for open-cut mining. The operations transform an in-situ grade control block model using a machine learning centric method which simulates phenomena in high-resolution, to model how the blast has transformed the in-situ material composition into the muckpile volume, and creates a model of the muckpile for creating and/or updating the post-blast dig plan.

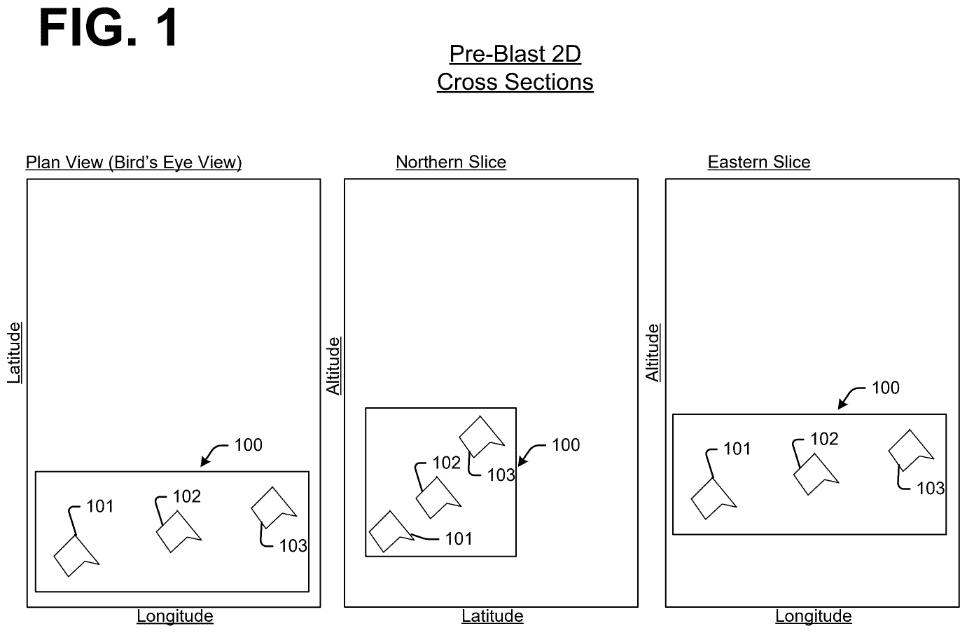

FIG. 1 illustrates an example actual geologic profile 100 of a mining operation pre-blast, in accordance with one or more implementations. The geologic profile 100 is a representation of the mine site showing the ground surface and a number of subsurface layers according to a depth profile. The subsurface layers may be characterized by geological layers (e.g., specific rocks or rock types) extending in depth beneath the ground surface.

Various ore deposits (e.g., minerals or other material of interest) to be mined are illustrated in the geologic profile 100 as deposits 101, 102, and 103. The ore deposit 101, 102, and 103 are shown at various locations in the subsurface layers in the geologic profile 100. Data used to represent the actual subsurface pre-blast may be obtained on site, according to conventional geology techniques, including but not limited to, analysis of drilled cores, site surveys, and other techniques for measuring and/or otherwise quantifying the geologic aspects of the mine site before any blasting occurs.

The geologic profile may be implemented to create a dig plan based on a predicted geologic profile of the mining operation post-blast, in accordance with one or more implementations. The term “post-blast” refers to the mine site after one or more explosion to loosen the rock structures. During the blast, rock structures, along with ore deposits may move or change location below the muckpile surface. In the example shown, a dig zone is determined based on efficient removal of the ore deposits 101, 102, and 103. For example, a dig zone may be characterized by a path to efficiently remove waste material and uncover (e.g., by heavy machinery) the ore deposits 101, 102, and 103.

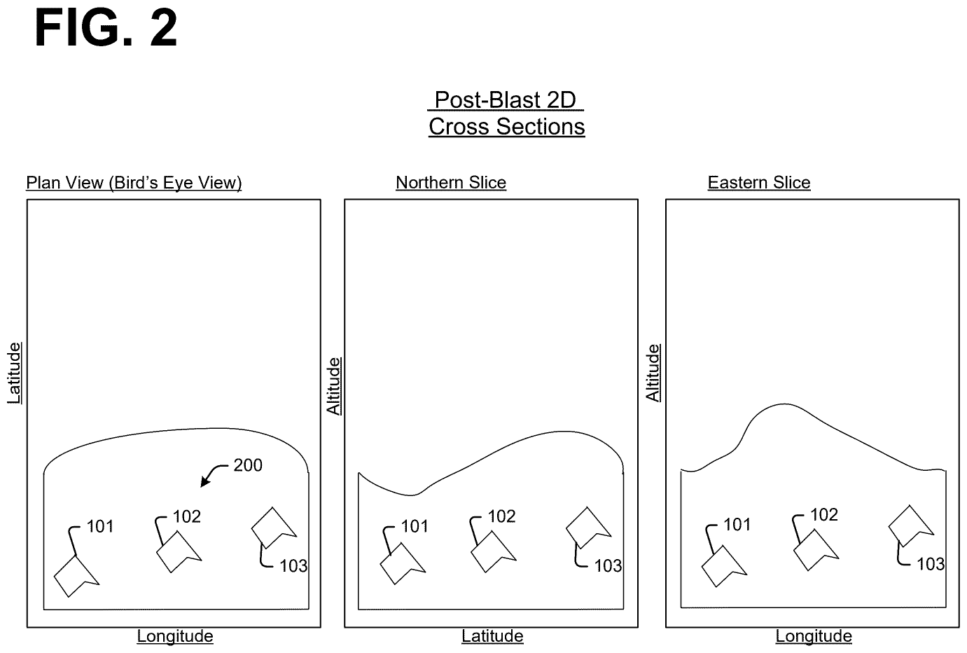

FIG. 2 illustrates an example actual geologic profile 200 of a mining operation post-blast, showing blast movement, in accordance with one or more implementations. Following the blast, the ore deposits 101, 102, and 103 may have moved and be located under the muckpile surface other than what was predicted (e.g., according to the dig plan shown). Accordingly, the post-blast dig plan should indicate that the waste material can be efficiently removed and the ore deposits 101, 102, and 103 efficiently recovered by the mining operations.

The dig plan may account for blast movement, in accordance with one or more implementations. The techniques described herein may be implemented to model the geologic structure of the mine site using computing techniques, taking into account blast movement, to create and/or update the post-blast dig plan. This is illustrated in the Figures where the geologic structure under the muckpile surface closely corresponds to the actual subsurface post-blast 200 shown in FIG. 2. That is, the locations of ore deposits 101, 102, and 103 in the model correspond to the actual locations of the ore deposits 101, 102, and 103, as seen in FIG. 2. Accordingly, the mining operations may proceed in a most efficient manner to remove waste material and recover the ore deposits.

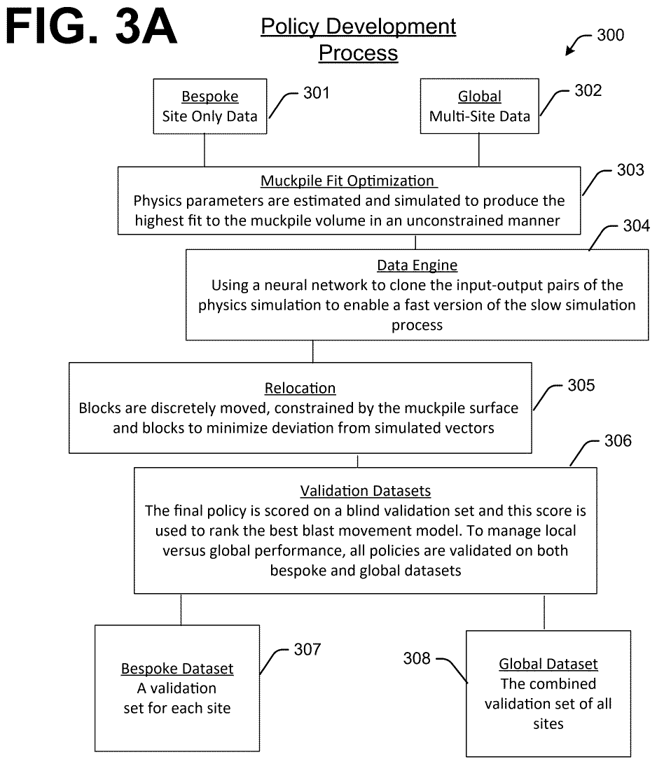

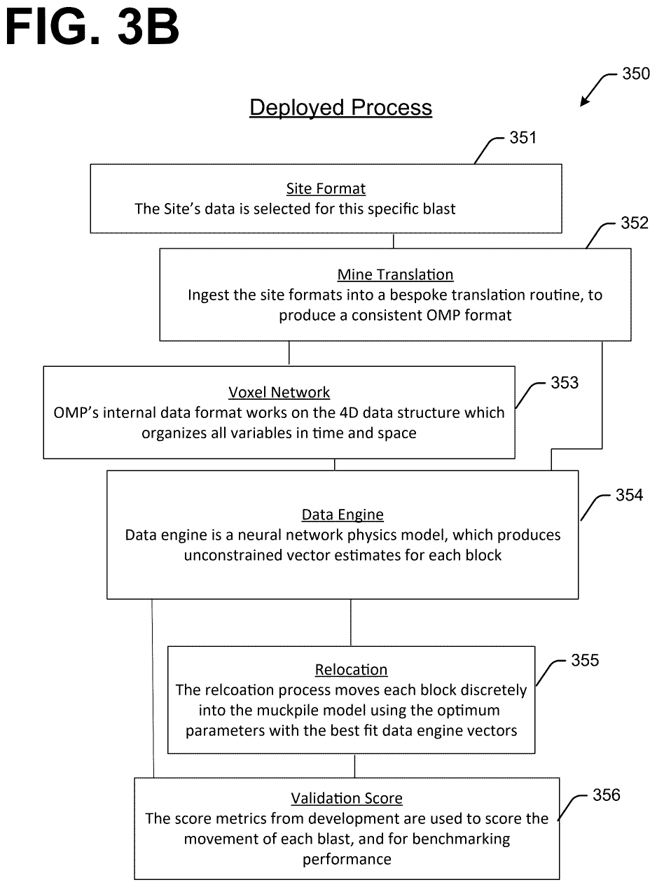

FIGS. 3A and 3B illustrate an example policy development process and deployment, in accordance with one or more implementations. In FIG. 3A, the policy development process 300 may include bespoke (or site only) data 301 and global (or multi-site) data 302. Muckpile fit optimization 303 includes estimating and simulating physics parameters to produce the highest fit to the muckpile volume and/or measured blast vector instrument (BVI) data in an unconstrained manner. The data engine 304 uses either a standalone physics simulation or a neural network to clone the input-output pairs of the physics simulation to enable a faster and more accurate version of the slow simulation process. During relocation 305, blocks are discretely moved, constrained by the muckpile surface and blocks to minimize deviation from simulated vectors. Validation datasets 306 includes scoring the final policy on a blind validation set. This score is used to rank the best blast movement model. To manage local versus global performance, all policies are validated on both the bespoke and global datasets. The bespoke dataset 307 includes each site's validation set for each site. The global dataset 308 includes the combined validation set of all sites.

An example of a deployed process 350 is illustrated in FIG. 3B. The site format 351 includes the site's bespoke data selected for this specific blast. The mine translation 352 includes the model ingesting the site formats into a bespoke translation routine, to produce a consistent OMP format. A voxel network 353 includes the OMP internal data format working on the 4D data structure which organizes all variables in time and space.

In a representative embodiment, the data engine 354 may be a physics simulation which calculates unconstrained final locations for each block. The configuration of the physics simulation preferably requires a set of tuning inputs to be provided (for example, via a tuning dataset), which configures the parameters of the physics simulation to accurately model each blast. These ‘moved’ block models can be used instead of the muckpile block model, despite the simulated block model not fitting to a regularized discrete grid. A validation score 356 from development is used to score the movement of each blast, and for benchmarking performance.

In a further representative embodiment, the data engine 354 may be a neural network physics model, which produces unconstrained vector estimates for each block. The relocation process 355 moves each block discretely into the muckpile block model using the optimum parameters with the best fit data engine vectors. As described above, a validation score 356 from development is used to score the movement of each blast, and for benchmarking performance.

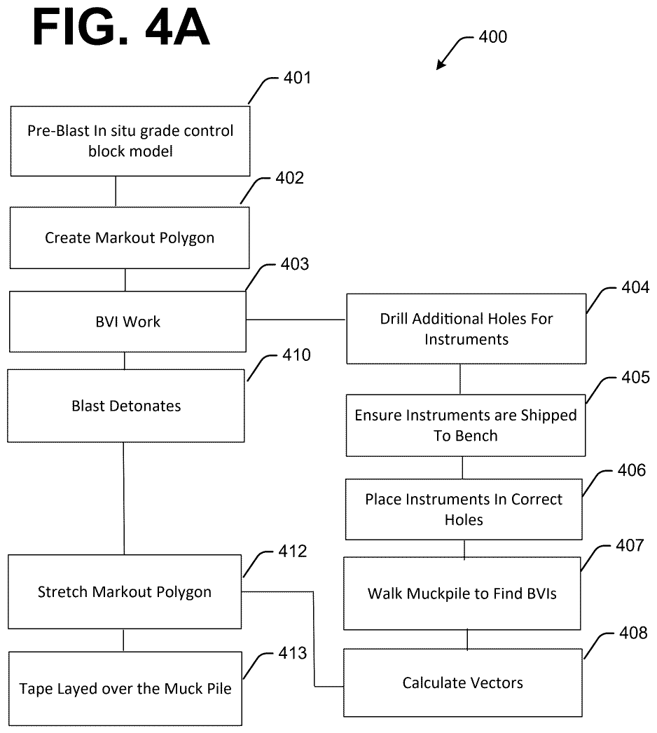

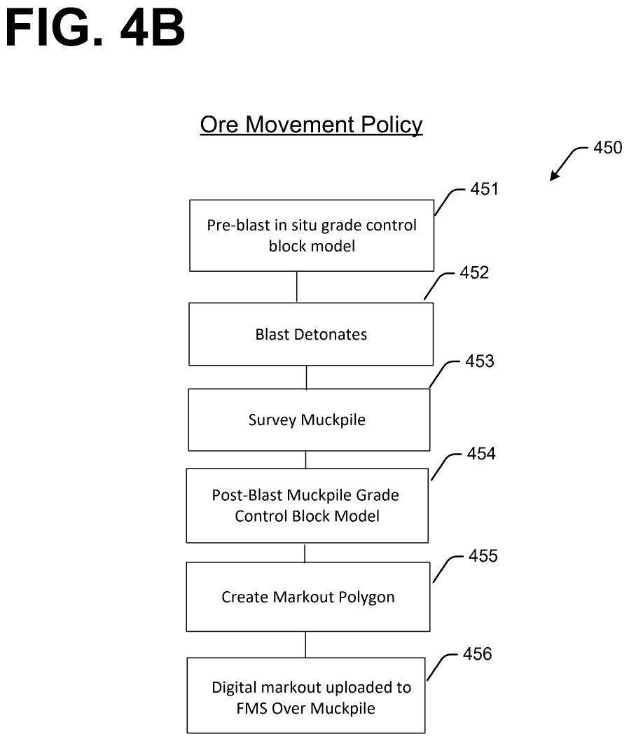

FIGS. 4A and 4B illustrate an example mining operation according to a policy development process 400 and corresponding ore movement policy 450, in accordance with one or more implementations. In FIG. 4A, operation 401 implements a pre-blast in situ grade control block model. Operation 402 creates a markout polygon. BVI works begins in operation 403 and includes operation 404 drilling additional holes for instruments, operation 405 ensuring the instruments are shipped to bench, operation 406 placing instruments in the correct holes, operation 407 walking the muckpile to find BVIs, and operation 408 calculating vectors. In operation 410, the blast detonates, and the muckpile is surveyed in operation 411. In operation 412, the markout polygon is stretched, and tape is laid over the muckpile in operation 413.

FIG. 4B illustrates an example ore movement policy 450. In operation 451, the pre-blast in situ grade control block model is implemented before the blast detonates in operation 452. In operation 453, the muckpile is surveyed. In operation 454, the post-blast muckpile grade control block model is implemented. In operation 455, a markout polygon is created. In operation 456, tape is laid over the muckpile 456.

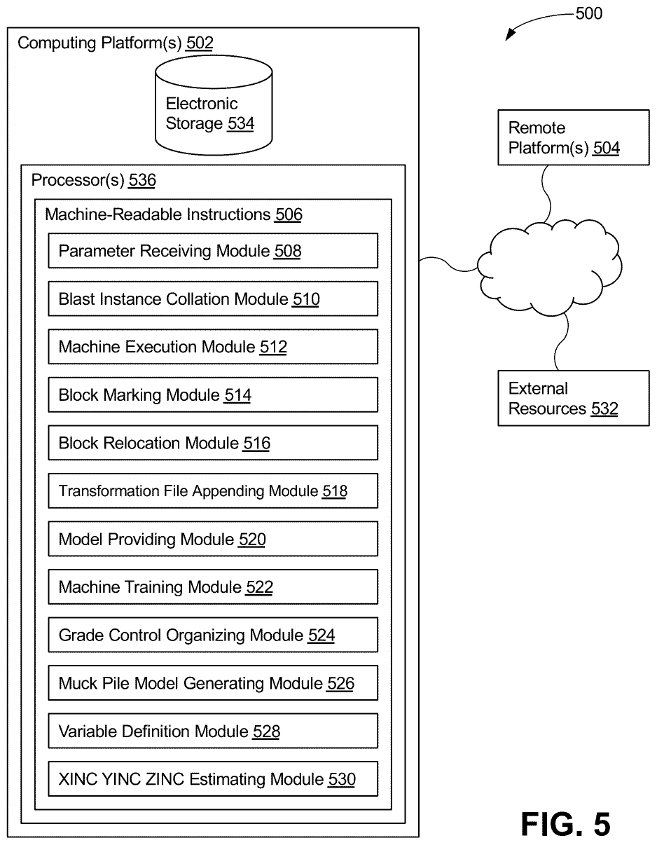

FIG. 5 illustrates a system 500 configured to model blast transformation of an in-situ block model into a muckpile block model for creating and/or updating a post-blast dig plan for a mine site, in accordance with one or more implementations. In some implementations, system 500 may include one or more computing platforms 502.

Computing platform(s) 502 may be configured to communicate with one or more remote platforms 504 according to a client/server architecture, a peer-to-peer architecture, and/or other architectures. Remote platform(s) 504 may be configured to communicate with other remote platforms via computing platform(s) 502 and/or according to a client/server architecture, a peer-to-peer architecture, and/or other architectures. Users may access system 500 via remote platform(s) 504.

Computing platform(s) 502 may be configured by machine-readable instructions 506. Machine-readable instructions 506 may include one or more instruction modules. The instruction modules may include computer program modules. The instruction modules may include one or more of parameter receiving module 508, blast instance collation module 510, machine execution module 512, block marking module 514, block relocation module 516, transformation file appending module 518, model providing module 520, machine training module 522, grade control organizing module 524, muckpile block model generating module 526, variable definition module 528, XINC YINC ZINC estimating module 530, and/or other instruction modules.

Parameter receiving module 508 may be configured to receive initial parameters of the in-situ material composition. It is noted that the term “material composition” as used herein refers to the individual components that make up a composition, such as the different rock and mineral types, quantity, and arrangement within the composition. It is also noted that any number and type of parameters may be utilized. Examples of parameters primarily include geologic profile data, such as but not limited to, geologic layers, composition and structure of geologic materials, mineral composition and types, water table, faults, cracks and fissures, mapping data. Examples of parameters may also include other types of data, including but not limited to, weather conditions and time. Parameters may be based on predictions and/or actual measurements or other data gathering techniques. Parameters may be site specific, and/or based on other sites (e.g., other mining sites having similar characteristics).

Blast instance collation module 510 may be configured to collate a blast instance file representing the initial parameters as a high-resolution block model encoding at least one of grade control, drill and blast parameters, site surveys (e.g., for a particular mining site), and custom strings (e.g., user-defined string). The term “blast” as used herein refers to mining techniques implemented to break up geologic structures (e.g., rock) and subsurface and geological layers, such as but not limited to, by drilling and dynamite. The term “high-resolution block model” as used herein refers to a block image of the geologic structure of a mining site characterized by fine detail. The term “grade control” as used herein refers to the classification of geologic material, for example into ore, low grade material, minerals, and waste material. The term “drill parameters” and “blast parameters” as used herein refers to locating and dept data referring to drilling operations into the geologic structure (e.g., for placement of dynamite), and the resulting movement of the geologic structure following an explosion such as by dynamite. The term “site surveys” refers to an accurate (e.g., measured) profile and topological layout of the geologic structure of the mine and movement of the surface and subsurface material in response to blast and/or other mining operations (e.g., digging and earth movement via heavy equipment). The term “Blast Vector Instruments (BVI's)” refers to any means of placing a physical device into the insitu volume before the blast, locating it post blast, and using the difference between these two points as a vector.

Machine execution module 512 may be configured to execute a machine learning simulation to generate a muckpile block model of in situ blocks. The term “simulation” as used herein refers to a re-creation of a real-world occurrence, based on a computing engine taking into consideration scientific principles (e.g., physics, geological principles, etc.). The term “muckpile block model” as used herein refers to a computer-generated model of the muckpile that results from a blast. The muckpile block model follows block modelling methods, such that every block exists on a regularised grid of nodes defined by the input block model. Every block location in the output model corresponds to a block location on the input model (i.e., blocks cannot be moved to a location outside of the regularised input model). This ensures that block centroids are appropriately spaced and do not overlap with adjacent blocks making it possible to import into other geological modelling software packages. Each in situ block may have a unique 3D predicted vector in the muckpile volume. The term “muckpile volume” as used herein refers to the material loosened and/or broken and/or moved due to the blast.

Block marking module 514 may be configured to mark particular blocks in the muckpile block model as absent air blocks such that these locations are now unavailable. Total available blocks within the muckpile block model may be equal to in situ blocks available to relocate. The term “particular blocks” as used herein refers to volumes of a particular type or grouping of material in the model. The term “absent air blocks” refers to model representations of “air” (e.g., lacking any material) that were present but have been removed from the model, e.g., due to lack of presence in the site survey post blast.

Block relocation module 516 may be configured to discretely relocate each block to a final location within the muckpile block model, fitting to the simulated 3D vectors. The term “final location” as used herein refers to a representation of material in the model that has been relocated to a position matching or substantially matching a location of the corresponding actual material at the mine site.

Transformation file appending module 518 may be configured to append a transformation file to an initial blast instance file. The term “transformation file” refers to a computer readable file including data relating the transformed or updated profile and/or other geologic information for the mine site. The term “initial blast instance file” as used herein refers to a computer readable file including data relating to data gathered following the blast prior to movement by heavy equipment.

Model providing module 520 may be configured to provide a transformed model for a user to generate an accurate mark out to update the post-blast dig plan based on changes a blast had on a material composition of the in-situ volume as defined in the muckpile block model. The term “accurate mark out” as used herein refers to changes to the predicted post-blast dig plan, based on the computer simulation model. The term “post-blast dig plan” refers to the plan to operate heavy machinery to move geologic material in the muckpile to efficiently arrive at minerals or other valuable resources being mined at the mine site.

Machine training module 522 may be configured to train a bespoke machine learning policy for the mine site. The term “bespoke” as used herein generally refers to an “off-the-shelf” machine learning policy without any customizations. It is noted, however, that the bespoke machine learning policy implemented herein may include at least some customization for the customer and/or mine site(s). The term “mine site” refers to the actual physical mine location, by geographic coordinates or otherwise. The bespoke machine learning policy may be based on a dataset of blasts. The term “dataset of blasts” as used herein refers to a collection of data or other information that can be manipulated by a computer. The dataset of blasts may be from the mine site. The dataset of blasts may be supplemented with another dataset of blasts from a different mine site. The term “different mine site” refers to a separate mine location, by geographic coordinates or otherwise. The term “different” (for example, in the context of different commodities or different material types) may be used to refer to an entirely different geographic location, or a separate location within a larger mine site. The bespoke machine learning policy may be a general policy based on generalized mine site data. The term “general policy” as used herein refers to a machine learning policy that has been established based on general machine learning techniques and has not been customized or tailored to any particular mine site. The term “generalized site data” refers to general information for mining operations that has not been customized or tailored to any particular mine site.

The bespoke machine learning policy may be based on all measured variables collected for the mine site to increase fidelity of the muckpile block model. The term “measured variables” as used herein refers to any parameters that are measured on-site at the mine, but are subject to change, e.g., due to blast movement. By way of non-limiting example, the bespoke machine learning policy may be reviewed for proficiency and performance, and is retrained regularly over a life of the mine site to maintain a defined proficiency. The term “defined proficiency” as used herein refers to a high degree of competence based on continued use and/or data input at an actual mine site.

Grade control organizing module 524 may be configured to organize a current grade control block model, drill and blast plans, actual drill and blast data, and survey data as soon as a post blast survey is completed. The term “drill and blast plans” as used herein refers to planning (usually by a site engineer) for drilling to place dynamite or other explosives, and then the resulting explosion or “blast”. The term “actual drill and blast data” refers to measured or observed or otherwise quantifiable data from the resulting drilling and blasting operations. The term “survey data” refers to information resulting from surveys taken at the mine site either before or after the drilling and blasting operations. The term “post blast survey” refers to surveys taken during and/or after the drilling and blasting operations. The term “Blast Vector Instruments (BVI's)” refers to any means of placing a physical device into the insitu volume before the blast, locating it post blast, and using the difference between these two points as a vector. Muckpile block model generating module 526 may be configured to generate the muckpile block model by transforming all input data types in a voxel network. The term “voxel network format” refers to an array of elements of volume that constitute a notational three-dimensional space in computer-based modeling and/or graphic simulation. By way of non-limiting example, the voxel network format may adhere to a nomenclature of IJK, XC, YC, ZC, TC, XINC, YINC, ZINC, TINC, and/or ATTR.

Variable definition module 528 may be configured to define a variable as an attribute of a 4-dimensional voxel in true 3D space and time according to the voxel network format. A 4-dimensional voxel includes the 3 physical dimensions, and time.

XINC YINC ZINC estimating module 530 may be configured to estimate XINC, YINC, and ZINC to factor for curvature of the earth.

In some implementations, by way of non-limiting example, the in-situ material composition may include at least one of a geological grade control block model, measurements of drilling and blasting parameters (e.g., information or data related to the drilling and blasting operations), planned drill and blast data, blast vector instrument (BVI) data, and surface scans (e.g., visual or by photograph or video) surveying a pre-blast surface (e.g., the ground surface prior to blasting operations) and a post-blast surface (e.g., the ground surface following blasting operations). In some implementations, where individual mine sites can have completely different input data. In some implementations, a pre-blast string (e.g., a sequence relating data prior to blasting operations) may define the in-situ volume and gives a user control of blocks that are allowed to move. In some implementations, a post-blast string (e.g., a sequence relating data after blasting operations) may define the muckpile volume and gives a user control of locations available to be filled by in-situ blocks. In some implementations, IJK may be a unique identifier (e.g., a numeric or alphanumeric string associated with a single entity) calculated from the other variables.

In some implementations, by way of non-limiting example, XC, YC, and ZC may be true 3D coordinates of a center of the voxel volume using true 3D longitude, latitude, and altitude coordinates. The term “voxel volume” as used herein refers to the three-dimensional equivalent of a pixel and the smallest distinguishable element of a 3D object. In some implementations, by way of non-limiting example, XINC, YINC, and ZINC may be lengths of each dimension and represent perfectly orthogonal dimensions. In some implementations, TC may be an initial point in time (e.g., time t=0) for a variable to be recorded. In some implementations, TINC may be a discrete window (or chosen interval) of time for a variable to be recorded. In some implementations, ATTR may be a specific attribute to be organized in a point in space time. The term “space time” as used herein refers to the concept of time and corresponding three-dimensional space in a 4D continuum.

In some implementations, computing platform(s) 502, remote platform(s) 504, and/or external resources 532 may be operatively linked via one or more electronic communication links. For example, such electronic communication links may be established, at least in part, via a network such as the Internet and/or other networks. It will be appreciated that this is not intended to be limiting, and that the scope of this disclosure includes implementations in which computing platform(s) 502, remote platform(s) 504, and/or external resources 532 may be operatively linked via some other communication media.

A given remote platform 504 may include one or more processors configured to execute computer program modules. The computer program modules may be configured to enable an expert or user associated with the given remote platform 504 to interface with system 500 and/or external resources 532, and/or provide other functionality attributed herein to remote platform(s) 504. By way of non-limiting example, a given remote platform 504 and/or a given computing platform 502 may include one or more of a server, a desktop computer, a laptop computer, a handheld computer, a tablet computing platform, a NetBook, a Smartphone, a gaming console, and/or other computing platforms.

External resources 532 may include sources of information outside of system 500, external entities participating with system 500, and/or other resources. In some implementations, some or all of the functionality attributed herein to external resources 532 may be provided by resources included in system 500.

Computing platform(s) 502 may include electronic storage 534, one or more processors 536, and/or other components. Computing platform(s) 502 may include communication lines, or ports to enable the exchange of information with a network and/or other computing platforms. Illustration of computing platform(s) 502 in FIG. 5 is not intended to be limiting. Computing platform(s) 502 may include a plurality of hardware, software, and/or firmware components operating together to provide the functionality attributed herein to computing platform(s) 502. For example, computing platform(s) 502 may be implemented by a cloud of computing platforms operating together as computing platform(s) 502.

Electronic storage 534 may comprise non-transitory storage media that electronically stores information. The electronic storage media of electronic storage 534 may include one or both of system storage that is provided integrally (i.e., substantially non-removable) with computing platform(s) 502 and/or removable storage that is removably connectable to computing platform(s) 502 via, for example, a port (e.g., a USB port, a firewire port, etc.) or a drive (e.g., a disk drive, etc.). Electronic storage 534 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 534 may include one or more virtual storage resources (e.g., cloud storage, a virtual private network, and/or other virtual storage resources).

Electronic storage 534 may store software algorithms, information determined by processor(s) 536, information received from computing platform(s) 502, information received from remote platform(s) 504, and/or other information that enables computing platform(s) 502 to function as described herein.

Processor(s) 536 may be configured to provide information processing capabilities in computing platform(s) 502. As such, processor(s) 536 may include one or more of a digital processor, an analog processor, a digital circuit designed to process information, an analog circuit designed to process information, a state machine, and/or other mechanisms for electronically processing information. Although processor(s) 536 is shown in FIG. 5 as a single entity, this is for illustrative purposes only. In some implementations, processor(s) 536 may include a plurality of processing units. These processing units may be physically located within the same device, or processor(s) 536 may represent processing functionality of a plurality of devices operating in coordination. Processor(s) 536 may be configured to execute modules 508, 510, 512, 514, 516, 518, 520, 522, 524, 526, 528, and/or 530, and/or other modules. Processor(s) 536 may be configured to execute modules 508, 510, 512, 514, 516, 518, 520, 522, 524, 526, 528, and/or 530, and/or other modules by software; hardware; firmware; some combination of software, hardware, and/or firmware; and/or other mechanisms for configuring processing capabilities on processor(s) 536. As used herein, the term “module” may refer to any component or set of components that perform the functionality attributed to the module. This may include one or more physical processors during execution of processor readable instructions, the processor readable instructions, circuitry, hardware, storage media, or any other components.

It should be appreciated that although modules 508, 510, 512, 514, 516, 518, 520, 522, 524, 526, 528, and/or 530 are illustrated in FIG. 5 as being implemented within a single processing unit, in implementations in which processor(s) 536 includes multiple processing units, one or more of modules 508, 510, 512, 514, 516, 518, 520, 522, 524, 526, 528, and/or 530 may be implemented remotely from the other modules. The description of the functionality provided by the different modules 508, 510, 512, 514, 516, 518, 520, 522, 524, 526, 528, and/or 530 described below is for illustrative purposes, and is not intended to be limiting, as any of modules 508, 510, 512, 514, 516, 518, 520, 522, 524, 526, 528, and/or 530 may provide more or less functionality than is described. For example, one or more of modules 508, 510, 512, 514, 516, 518, 520, 522, 524, 526, 528, and/or 530 may be eliminated, and some or all of its functionality may be provided by other ones of modules 508, 510, 512, 514, 516, 518, 520, 522, 524, 526, 528, and/or 530. As another example, processor(s) 536 may be configured to execute one or more additional modules that may perform some or all of the functionality attributed below to one of modules 508, 510, 512, 514, 516, 518, 520, 522, 524, 526, 528, and/or 530.

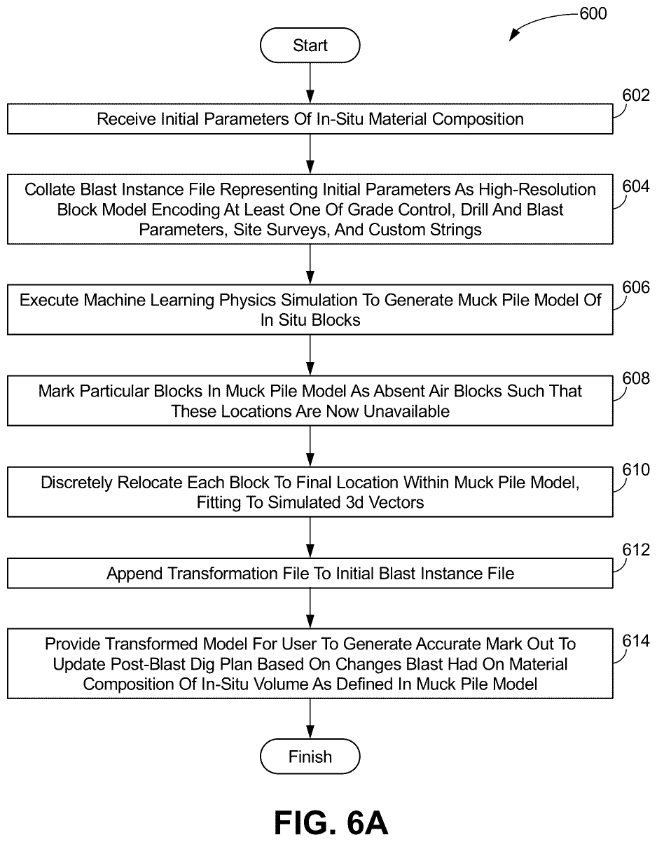

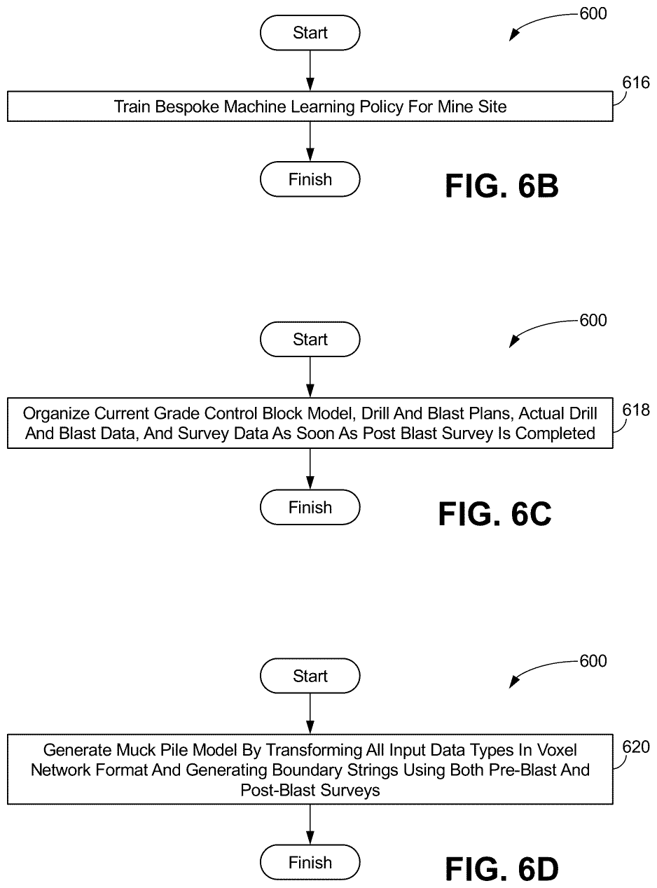

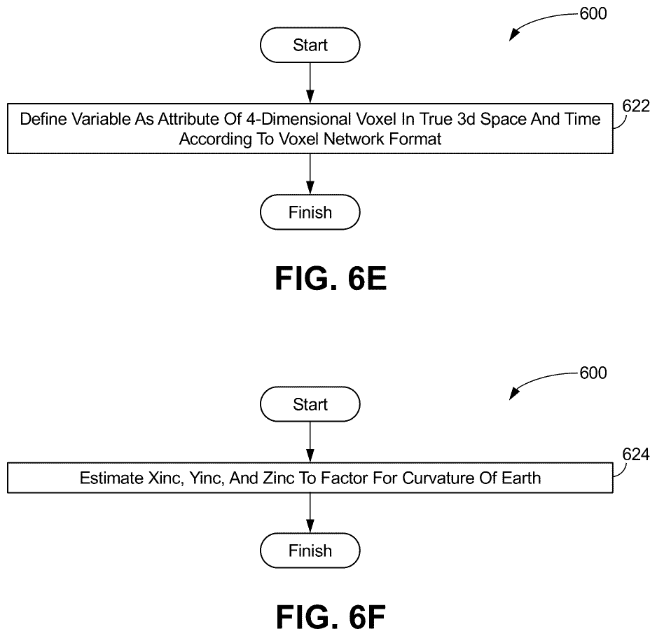

FIGS. 6A, 6B, 6C, 6D, 6E, and/or 6F illustrates a method 600 to model blast transformation of an in-situ material composition into a muckpile volume for creating and/or updating a post-blast dig plan for a mine site, in accordance with one or more implementations. The operations of method 600 presented below are intended to be illustrative. In some implementations, method 600 may be accomplished with one or more additional operations not described, and/or without one or more of the operations discussed. Additionally, the order in which the operations of method 600 are illustrated in FIGS. 6A, 6B, 6C, 6D, 6E, and/or 6F and described below is not intended to be limiting.

In some implementations, method 600 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 600 in response to instructions stored electronically on an electronic storage medium. The one or more processing devices may include one or more devices configured through hardware, firmware, and/or software to be specifically designed for execution of one or more of the operations of method 600.

FIG. 6A illustrates method 600, in accordance with one or more implementations.

An operation 602 may include receiving initial parameters of the in-situ material composition. Operation 602 may be performed by one or more hardware processors configured by machine-readable instructions including a module that is the same as or similar to parameter receiving module 508, in accordance with one or more implementations.

An operation 604 may include collating a blast instance file representing the initial parameters as a high-resolution block model encoding at least one of grade control, drill and blast parameters, site surveys, and custom strings. Operation 604 may be performed by one or more hardware processors configured by machine-readable instructions including a module that is the same as or similar to blast instance collation module 510, in accordance with one or more implementations.

An operation 606 may include executing a machine learning simulation to generate a muckpile block model of in situ blocks. Each in situ block may have a unique 3D predicted vector in the muckpile volume. Operation 606 may be performed by one or more hardware processors configured by machine-readable instructions including a module that is the same as or similar to machine execution module 512, in accordance with one or more implementations.

An operation 608 may include marking particular blocks in the muckpile block model as absent air blocks (although, not necessarily absent of density) such that these locations are now unavailable. Total available blocks within the muckpile block model may be equal to in situ blocks available to relocate. Operation 608 may be performed by one or more hardware processors configured by machine-readable instructions including a module that is the same as or similar to block marking module 514, in accordance with one or more implementations.

An operation 610 may include discretely relocating each block to a final location within the muckpile block model, fitting to the simulated 3D vectors. Operation 610 may be performed by one or more hardware processors configured by machine-readable instructions including a module that is the same as or similar to block relocation module 516, in accordance with one or more implementations.

An operation 612 may include appending a transformation file to an initial blast instance file. Operation 612 may be performed by one or more hardware processors configured by machine-readable instructions including a module that is the same as or similar to transformation file appending module 518, in accordance with one or more implementations.

An operation 614 may include providing a transformed model for a user to generate an accurate mark out to update the post-blast dig plan based on changes a blast had on a material composition of the in-situ volume as defined in the muckpile block model. Operation 614 may be performed by one or more hardware processors configured by machine-readable instructions including a module that is the same as or similar to model providing module 520, in accordance with one or more implementations.

FIG. 6B illustrates method 600, in accordance with one or more implementations.

An operation 616 may include further including training a bespoke machine learning policy for the mine site. Operation 616 may be performed by one or more hardware processors configured by machine-readable instructions including a module that is the same as or similar to machine training module 522, in accordance with one or more implementations.

FIG. 6C illustrates method 600, in accordance with one or more implementations.

An operation 618 may include further including organizing a current grade control block model, drill and blast plans, actual drill and blast data, blast vector instrument (BVI) data, and survey data as soon as a post blast survey is completed. Operation 618 may be performed by one or more hardware processors configured by machine-readable instructions including a module that is the same as or similar to grade control organizing module 524, in accordance with one or more implementations.

FIG. 6D illustrates method 600, in accordance with one or more implementations.

An operation 620 may include further including generating the muckpile block model by transforming all input data types in a voxel network format and generating boundary strings using both pre-blast and post-blast surveys. Operation 620 may be performed by one or more hardware processors configured by machine-readable instructions including a module that is the same as or similar to muckpile block model generating module 526, in accordance with one or more implementations.

FIG. 6E illustrates method 600, in accordance with one or more implementations.

An operation 622 may include further including defining a variable as an attribute of a 4-dimensional voxel in true 3D space and time according to the voxel network format. Operation 622 may be performed by one or more hardware processors configured by machine-readable instructions including a module that is the same as or similar to variable definition module 528, in accordance with one or more implementations.

FIG. 6F illustrates method 600, in accordance with one or more implementations.

An operation 624 may include further including estimating XINC, YINC, and ZINC to factor for curvature of the earth. Operation 624 may be performed by one or more hardware processors configured by machine-readable instructions including a module that is the same as or similar to XINC YINC ZINC estimating module 530, in accordance with one or more implementations.

Although the present technology has been described in detail for the purpose of illustration based on what is currently considered to be the most practical and preferred implementations, it is to be understood that such detail is solely for that purpose and that the technology is not limited to the disclosed implementations, but, on the contrary, is intended to cover modifications and equivalent arrangements that are within the spirit and scope of the appended claims. For example, it is to be understood that the present technology contemplates that, to the extent possible, one or more features of any implementation can be combined with one or more features of any other implementation.

1. A system configured to model blast transformation of an in-situ material composition into a muckpile volume for generating a model for a post-blast dig plan for a mine site, the system comprising:
one or more hardware processors configured by machine-readable instructions to:
receive initial parameters of the in-situ material composition;
collate a blast instance file representing the initial parameters as a high-resolution block model encoding at least one of grade control, drill and blast parameters, site surveys, blast vector instrument (BVI) data, and custom strings;
execute a simulation and/or machine learning simulation to generate a muckpile block model of in situ blocks, each in situ block having a unique 3D predicted vector in the muckpile volume;
mark particular blocks in the muckpile block model as absent air blocks such that these locations are now unavailable, and total available blocks within the muckpile block model being equal to in situ blocks available to relocate;
discretely relocate each block to a final location within the muckpile block model, fitting to the simulated 3D vectors;
append a transformation file to an initial blast instance file; and
provide a transformed model for a user to generate an accurate mark out to update the post-blast dig plan based on changes a blast had on a material composition of the in-situ volume as defined in the muckpile block model.

2. The system of claim 1, wherein the in-situ material composition comprises at least one of a geological grade control block model, measurements of drilling and blasting parameters, planned and/or actual drill and blast data, blast vector instrument (BVI) data, and surface scans surveying a pre-blast surface and a post-blast surface.

3. The system of claim 1, wherein the one or more hardware processors are further configured by machine-readable instructions to train a bespoke machine learning policy for the mine site.

4. The system of claim 3, wherein the bespoke machine learning policy is based on a dataset of blasts.

5. The system of claim 4, wherein the dataset of blasts is from the mine site.

6. The system of claim 4, wherein the dataset of blasts is supplemented with another dataset of blasts from a different mine site.

7. The system of claim 3, wherein the bespoke machine learning policy is a general policy based on generalized mine site data.

8. A method to model blast transformation of an in-situ material composition into a muckpile volume for generating a model for a post-blast dig plan for a mine site, the method comprising:
receiving initial parameters of the in-situ material composition;
collating a blast instance file representing the initial parameters as a high-resolution block model encoding at least one of grade control, drill and blast parameters, site surveys, blast vector instrument (BVI) data, and custom strings;
executing a machine learning simulation to generate a muckpile block model of in situ blocks, each in situ block having a unique 3D predicted vector in the muckpile volume;
marking particular blocks in the muckpile block model as absent air blocks such that these locations are now unavailable, and total available blocks within the muckpile block model being equal to in situ blocks available to relocate;
discretely relocating each block to a final location within the muckpile block model, fitting to the simulated 3D vectors;
appending a transformation file to an initial blast instance file; and
providing a transformed model for a user to generate an accurate mark out for the post-blast dig plan based on changes a blast had on a material composition of the in-situ volume as defined in the muckpile block model.

9. The method of claim 8, wherein the in-situ material composition comprises at least one of a geological grade control block model, measurements of drilling and blasting parameters, planned drill and blast data, blast vector instrument (BIV) data, and surface scans surveying a pre-blast surface and a post-blast surface.

10. The method of claim 8, further comprising training a bespoke machine learning policy for the mine site.

11. The method of claim 10, wherein the bespoke machine learning policy is based on a dataset of blasts.

12. The method of claim 11, wherein the dataset of blasts is from the mine site.

13. The method of claim 11, wherein the dataset of blasts is supplemented with another dataset of blasts from a different mine site.

14. The method of claim 10, wherein the bespoke machine learning policy is a general policy based on generalized mine site data.

15. A non-transient computer-readable storage medium having instructions embodied thereon, the instructions being executable by one or more processors to perform a method to model blast transformation of an in-situ material composition into a muckpile volume for creating and/or updating a post-blast dig plan for a mine site, the method comprising:
receiving initial parameters of the in-situ material composition;
collating a blast instance file representing the initial parameters as a high-resolution block model encoding at least one of grade control, drill and blast parameters, site surveys, blast vector instrument (BVI) data, and custom strings;
executing a machine learning simulation to generate a muckpile block model of in situ blocks, each in situ block having a unique 3D predicted vector in the muckpile volume;
marking particular blocks in the muckpile block model as absent air blocks such that these locations are now unavailable, and total available blocks within the muckpile block model being equal to in situ blocks available to relocate;
discretely relocating each block to a final location within the muckpile block model, fitting to the simulated 3D vectors;
appending a transformation file to an initial blast instance file; and
providing a transformed model for a user to generate an accurate mark out to update the post-blast dig plan based on changes a blast had on a material composition of the in-situ volume as defined in the muckpile block model.

16. The computer-readable storage medium of claim 15, wherein the material composition comprises at least one of a geological grade control block model, measurements of drilling and blasting parameters, planned drill and blast data, blast vector instrument (BVI) data, and surface scans surveying a pre-blast surface and a post-blast surface.

17. The computer-readable storage medium of claim 15, wherein the method further comprises training a bespoke machine learning policy for the mine site.

18. The computer-readable storage medium of claim 17, wherein the bespoke machine learning policy is based on a dataset of blasts.

19. The computer-readable storage medium of claim 18, wherein the dataset of blasts is from the mine site.

20. The computer-readable storage medium of claim 18, wherein the dataset of blasts is supplemented with another dataset of blasts from a different mine site.
